(19) United States
(12) Patent Application Publication
(10) Pub. No.: US 2006/0141740 A1
(43) Pub. Date: Jun. 29, 2006

(54) Semiconductor device with shallow trench isolation and a manufacturing method thereof

(75) Inventor: Dae-Ho Jeong, Seoul (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignee: DongbuAnam Semiconductor Inc.

(21) Appl. No.: 11/316,543

(22) Filed: Dec. 20, 2005

(30) Foreign Application Priority Data
Dec. 23, 2004 (KR) 10-2004-0111551

(51) Int. Cl. H01L 21/76

(52) U.S. Cl. 438/424; 438/442

(57) ABSTRACT

An exemplary method of manufacturing a shallow trench isolation structure in a semiconductor device includes forming a first trench region by etching the semiconductor substrate to a predetermined depth, forming a first oxide layer on the entire surface of the semiconductor substrate so as to fill the first trench region, forming an epitaxial layer in an active region on the semiconductor substrate, and forming a second oxide layer so as to fill a gap between portions of the epitaxial layer. Consequently, a void due to incomplete gap-filling of conventional shallow trench isolation structures may be prevented by a two step gap-fill process using the epitaxial layer.

### CROSS-REFERENCE TO RELATED APPLICATION

This application claims priority to and the benefit of Korean Patent Application No. 10-2004-0111551, filed in the Korean Intellectual Property Office on Dec. 23, 2004, the entire contents of which are incorporated herein by reference.

### BACKGROUND OF THE INVENTION

(a) Field of the Invention

The present invention relates to a semiconductor device and a manufacturing method thereof. More particularly, the present invention relates to a semiconductor device having a shallow trench isolation (STI) structure and a manufacturing method thereof.

(b) Description of the Related Art

Recently, as semiconductor devices have become more highly integrated, more advanced and precise technology has been developed for device isolation.

Such a device isolation process technology generally includes higher level techniques than other, earlier processes. Typical device isolation technologies such as local oxidation of silicon (LOCOS) and selective polysilicon oxidation have been introduced to satisfy a design rule for higher integration. However, recently they have reached a practical limit.

A device isolation process using trench technology has been introduced to overcome such a limit. According to the device isolation process, a trench is formed on a semiconductor substrate and filled with a CVD oxide layer. By using such a trench technology, an area required for device isolation can be reduced. Thus, trench-based technology has been widely used as semiconductor devices have become more highly integrated.

As a result, among submicron MOSFET device isolation technologies, either a LOCOS process or a shallow trench isolation (STI) process may be selected according to characteristics of the device.

As the size of MOSFET devices has been reduced to a submicron size, a device structure thereof has become finer and more highly integrated, and thus some process problems have resulted.

FIG. 1 is a cross-sectional view illustrating a semiconductor device having shallow trench isolation (STI) formed by a typical method.

Referring to FIG. 1, in an STI structure formed by the typical method, a pad oxide layer 112 is formed on a silicon substrate 111 to a thickness of 150-300 Å. The pad oxide layer 112 is used as a buffer layer for reducing stress forces from a nitride layer 113 on the silicon substrate 111 and as a protective layer for the silicon substrate 111 during an ion implantation process.

The nitride layer 113 is formed on the pad oxide layer 112 to a thickness of 1000-3000 Å. Subsequently, after patterning a mask for opening a trench region, the nitride layer 113 and the pad oxide layer 112 in the trench region are selectively removed, and a part of the silicon substrate 111 is etched to form the trench.

As the size of semiconductor devices has been reduced to a submicron size, a critical dimension of STI should be reduced. At this time, when the trench is filled with an oxide layer, the oxide layer 114 cannot fully fill a gap of the trench, and thus a void may be unexpectedly formed, as shown by reference numeral A. Consequently, qualities of the STI, such as an insulation characteristic, may deteriorate when such a void forms therein. Furthermore, in a subsequent process of forming a polysilicon gate, polysilicon may be deposited in the void so as to deteriorate further the quality of the STI.

The above information disclosed in this Background section is only for enhancement of understanding of the background of the invention, and therefore, it may contain information that does not form prior art or other information that is already known in this or any other country to a person of ordinary skill in the art.

### SUMMARY OF THE INVENTION

The present invention has been made in an effort to provide a semiconductor device and a manufacturing method thereof having advantages of preventing (or reducing the incidence on voids in shallow trench isolation structures.

An exemplary manufacturing method according to an embodiment of the present invention may include forming a pad oxide layer on a semiconductor substrate; forming a pad nitride layer on the pad oxide layer; forming a trench pattern by selectively removing portions of the pad nitride layer and the pad oxide layer; forming a first trench region by etching the semiconductor substrate to a predetermined depth; forming a first oxide layer on the entire surface of the semiconductor substrate so as to fill the first trench region; forming an epitaxial layer in an active region on the semiconductor substrate; and forming a second oxide layer so as to fill a gap within the epitaxial layer.

In a further embodiment, the first trench region may be formed by etching the semiconductor substrate to a depth of about one-half of the total (target) trench depth to be formed.

The first oxide layer may be formed by sequentially (5-10 times) forming oxide sublayers. At this time, each oxide sublayer may have a thickness of 500-1000 Å.

After forming the first oxide layer, the entire surface may be planarized by chemical mechanical polishing (CMP). Consequently, the CMP may fully remove the pad nitride layer, and leave the pad oxide layer at a thickness of 50-150 Å.

The epitaxial layer may have a thickness of about one-half of the total (target) trench depth. Before forming the epitaxial layer, the pad oxide may be removed (e.g., by using hydrogen gas).

After forming the second oxide layer, the entire surface may be planarized by chemical mechanical polishing (CMP), and the second oxide layer may have a thickness of 100-500 Å over the epitaxial layer.

The pad oxide layer may have a thickness of 100-300 Å.

The pad nitride layer may have a thickness of 1000-3000 Å.

In addition, an exemplary semiconductor device according to an embodiment of the present invention includes a semiconductor substrate, a first oxide layer filling a first trench region in the semiconductor substrate, an epitaxial layer in an active region on the semiconductor substrate, and a second oxide layer filling a gap within the epitaxial layer.

In a further embodiment, the first gap-fill oxide layer may comprise 5-10 sequentially formed oxide layers.

A thickness of the first trench region may be about one-half of the total (target) trench depth.

A thickness of the epitaxial layer may be about one-half of the total (target) trench depth.

An oxide layer having a thickness of 100-500 Å may be formed on the epitaxial layer.

Therefore, according to an exemplary embodiment of the present invention, a void due to incomplete gap-filling of shallow trench isolation may be prevented by a two-step gap-fill process using an epitaxial layer in the active area. In addition, the epitaxial layer may enable precise control of a critical dimension and provide edge corner rounding in a shallow trench isolation structure.

### BRIEF DESCRIPTION OF THE DRAWINGS

FIG. 1 is a cross-sectional view illustrating a semiconductor device having a shallow trench isolation (STI) structure formed by a typical method.

FIG. 2 is a cross-sectional view illustrating a semiconductor device having an STI structure according to an exemplary embodiment of the present invention.

FIG. 3A to FIG. 3H are cross-sectional views showing principal stages of a semiconductor device manufacturing method according to an exemplary embodiment of the present invention.

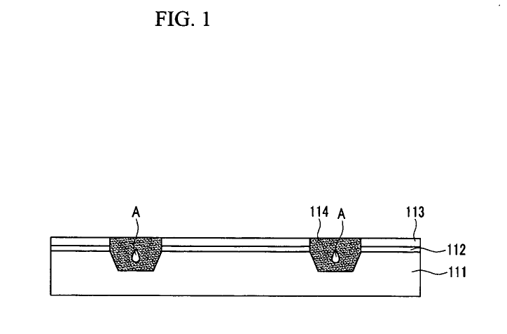

### DETAILED DESCRIPTION OF THE EMBODIMENTS

An exemplary embodiment of the present invention will hereinafter be described in detail with reference to the accompanying drawings.

According to an exemplary embodiment of the present invention, in order to prevent a void due to incomplete gap-filling of shallow trench isolation, a two step gap-fill process using an epitaxial layer is performed.

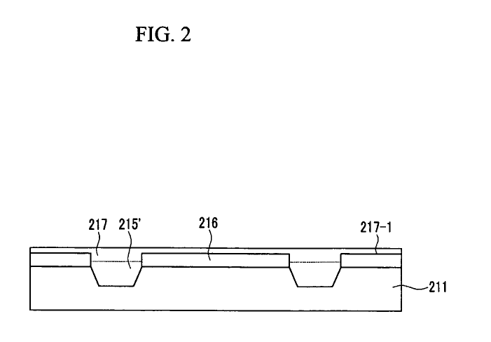

FIG. 2 is a cross-sectional view illustrating a semiconductor device having STI according to an exemplary embodiment of the present invention.

Referring to FIG. 2, the semiconductor device according to an exemplary embodiment of the present invention includes a first oxide layer 215′ filling a trench region in a semiconductor substrate 211, an epitaxial layer 216, and a second oxide layer 217. Such a two step gap-fill structure can prevent void that frequently occur in conventional one-step methods for forming STI. At this time, reference numeral 217-1 indicates an oxide layer having a thickness of 100-500 Å remaining on the epitaxial layer 216.

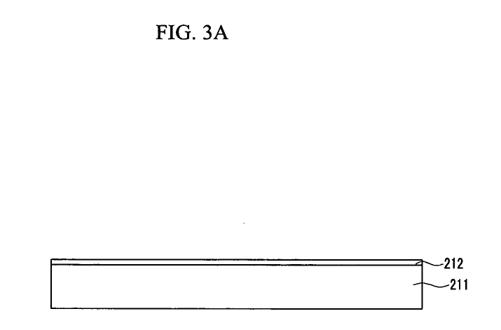

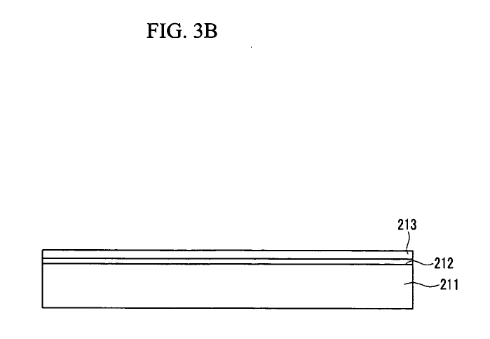

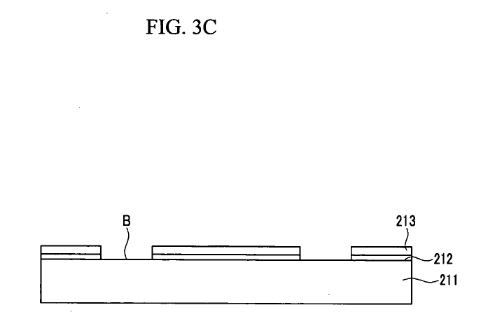

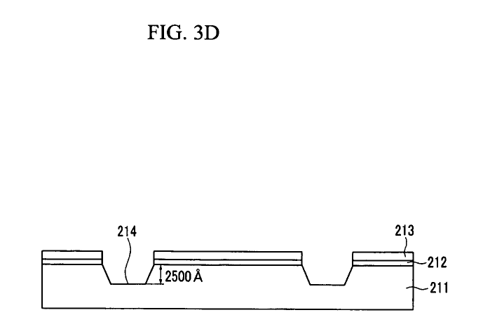

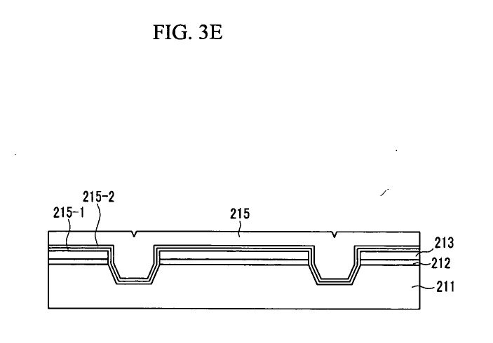

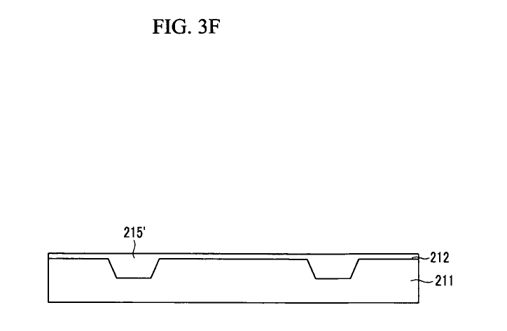

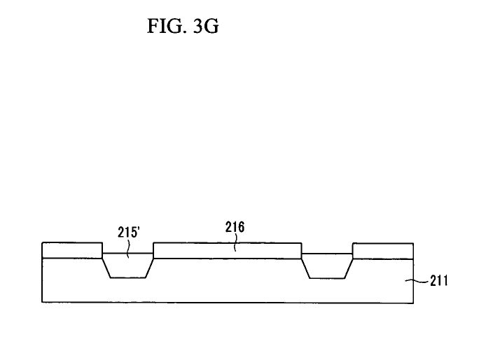

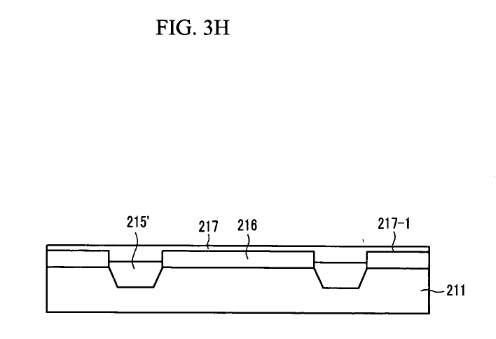

An exemplary manufacturing method according to an embodiment of the present invention will hereinafter be described in detail with reference to FIGS. 3A to 3H.

First, referring to FIG. 3A, a pad oxide layer 212 is formed on a semiconductor substrate 211. In more detail, the pad oxide layer 212 may be formed to a thickness of 100-300 Å by oxidizing the semiconductor substrate 211 (typically by conventional wet or dry thermal silicon oxidation), although it is possible that the pad oxide layer 212 (which typically comprises or consists essentially of silicon dioxide) can be formed by conventional chemical vapor deposition (CVD), plasma-assisted deposition, etc..

Subsequently, referring to FIG. 3B, a nitride layer 213 is deposited on the pad oxide layer 212. In more detail, the nitride layer 213 may be formed by low pressure chemical vapor deposition (LPCVD) using a mixture of SiH₂Cl₂ gas and NH₃ gas. At this time, the nitride layer 213 may be formed to a thickness of 1000-3000 Å.

Referring to FIG. 3C, after a mask pattern (not shown) for a trench is formed on the pad oxide layer 212 and the nitride layer 213, both layers are selectively removed in the trench region. Reference numeral B indicates a region whereon the pad oxide layer and the nitride layer are removed. Subsequently, referring to FIG. 3D, after removing the pad oxide layer and the nitride layer, the silicon substrate is etched for forming a first trench region. At this time, the silicon substrate may be etched to a depth of a half of the total trench depth to be formed. For example, if the total trench depth to be formed is 5000 Å, then the silicon substrate may be etched to a depth of 2500 Å. However, the depth of the trench in the silicon substrate 211 may be more or less than one-half, depending on the thicknesses of the pad oxide layer 212, nitride layer 213, the photoresist deposited on nitride layer 213 prior to etching the trench 214, the subsequently formed epitaxial layer, and the desired or target thickness of the STI structure. Reference numeral 214 indicates a region wherein the silicon substrate is etched.

Referring to FIG. 3E and to FIG. 3F, a first oxide layer is formed so as to fill the first trench region, and it is then planarized by chemical mechanical polishing (CMP). In forming the first oxide layer, a thin oxide layer may be sequentially (5-10 times) formed to a total thickness of 5000 Å, as shown in FIG. 3E. Because the oxide layers are deposited in a manner intended to fill a “gap” between sidewalls of the trench 214, the first oxide layer 215 may be considered to be a “gap-fill” oxide. Then, the oxide layer 215 is planarized by CMP, as shown in FIG. 3F. The pad nitride layer 213 is fully removed, and the pad oxide layer 212 may remain at a thickness of 50-150 Å after CMP. Reference numeral 215′ indicates the first trench region after the first gap-fill process.

Referring to FIG. 3G, an epitaxial layer 216 (preferably of silicon or silicon-germanium) is formed on the remaining pad oxide layer 212. In more detail, an epitaxial layer 216 is formed in an active region of the substrate 211. In a previous gap-fill process, the first trench region having a depth of 2500 Å is pre-formed, so the epitaxial layer 216 is formed to a thickness of 2500 Å for forming an STI having a total depth of 5000 Å. At this time, before forming an epitaxial layer, the pad oxide may be removed by using hydrogen (H₂) gas (which may be plasma-activated during the pad oxide removal). Alternatively, the remaining pad oxide layer 212 can be removed with a conventional wet etch (e.g., using dilute aqueous HF or buffered dilute aqueous HF).

Referring to FIG. 3H, a second oxide layer 217 is formed and planarized by CMP. In more detail, a second silicon dioxide layer may be deposited sufficiently to fill the gaps between portions of the epitaxial layer 216b and planarized by CMP. At this time, in order to prevent damage to the epitaxial layer 216, the second gap-fill oxide layer may not be fully removed, and thus an oxide layer 217-1 having a thickness of a 100-500 Å may be left to a thickness of 100-500 Å on the epitaxial layer 216. The oxide layer 217-1 may be removed as described above for removing the remaining the pad oxide layer 212 (see the discussion of FIG. 3G above), resulting in the second oxide layer 217 having about the same thickness as the epitaxial layer 216 (e.g., about 2500 Å in the example discussed in the preceding paragraph).

According to an exemplary embodiment of the present invention, a void due to incomplete gap-filling in a method of making a shallow trench isolation structure may be prevented by a two step process using an epitaxial layer.

In addition, the epitaxial layer may enable precise control of a critical dimension and prevent undesirable edge corner rounding in a shallow trench isolation structure, while at the same time, providing desirable corner rounding in the upper corner of the silicon active area immediately adjacent to the STI structure.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of manufacturing a shallow trench isolation structure in a semiconductor device, comprising:
forming a first trench region by etching a semiconductor substrate to a predetermined depth, using patterned pad nitride and pad oxide layers thereon as a mask;
forming a first oxide layer so as to fill a gap of the first trench region;
forming an epitaxial layer in an active region on the semiconductor substrate; and
forming a second gap-fill oxide layer so as to fill a gap within the epitaxial layer.

2. The method of claim 1, wherein forming the first trench region comprises by etching the semiconductor substrate to a depth of about half of a total target trench depth.

3. The method of claim 1, wherein forming the first oxide layer comprises sequentially forming 5-10 oxide sublayers.

4. The method of claim 3, wherein each oxide sublayer has a thickness of 500-1000 Å.

5. The method of claim 1, further comprising, after forming the first oxide layer, planarizing the entire surface by chemical mechanical polishing (CMP).

6. The method of claim 5, wherein the CMP comprises fully removing the pad nitride layer, and leaving the pad oxide layer at a thickness of 50-150 Å.

7. The method of claim 1, wherein the epitaxial layer has a thickness of about one-half of a total target trench depth.

8. The method of claim 1, further comprising, before forming the epitaxial layer, removing the patterned pad oxide layer.

9. The method of claim 1, further comprising, after forming the second oxide layer, planarizing the entire surface by chemical mechanical polishing (CMP).

10. The method of claim 9, wherein the second gap-fill oxide layer has a thickness of 100-500 Å after said CMP.

11. The method of claim 1, wherein the patterned pad oxide layer has a thickness of 100-300 Å.

12. The method of claim 1, wherein the patterned pad nitride layer has a thickness of 1000-3000 Å.

13. The method of claim 1, further comprising forming a pad oxide layer on the semiconductor substrate prior to forming the first trench region.

14. The method of claim 13, further comprising forming a pad nitride layer on the pad oxide layer prior to forming the first trench region.

15. The method of claim 14, further comprising selectively removing portions of the pad nitride layer and the pad oxide layer to form the patterned pad nitride and pad oxide layers.

16. The method of claim 1, wherein forming the first oxide layer comprises depositing the first oxide layer on the entire surface of the semiconductor substrate.

17. A semiconductor device having a shallow trench isolation structure, comprising:
a semiconductor substrate;
a first oxide layer filling a first trench in the semiconductor substrate;
an epitaxial layer in an active region on the semiconductor substrate; and
a second oxide layer on the first oxide layer, filling a gap within the epitaxial layer.

18. The semiconductor device of claim 17, wherein the first oxide layer comprises 5-10 sequentially formed oxide sublayers.

19. The semiconductor device of claim 17, wherein a thickness of the first trench is about one-half of a total target trench depth.

20. The semiconductor device of claim 19, wherein the epitaxial layer has a thickness of about one-half of the total target trench depth.
